(19) United States
(12) Patent Application Publication
(10) Pub. No.: US 2010/0261309 A1
(43) Pub. Date: Oct. 14, 2010

(54) METHOD OF MANUFACTURING SEMICONDUCTOR DEVICE

(75) Inventor: Toshiyuki Tateishi, Ota-ku (JP)

Correspondence Address: GREER, BURNS & CRAIN, 300 S WACKER DR, 25TH FLOOR, CHICAGO, IL, 60606, US

(73) Assignee: DISCO CORPORATION, Tokyo (JP)

(21) Appl. No.: 12/722,762

(22) Filed: Mar. 12, 2010

(30) Foreign Application Priority Data
Apr. 9, 2009 (JP) 2009-095075

(51) Int. Cl. H01L 21/56

(52) U.S. Cl. 438/107; 257/E21.502

(57) ABSTRACT

A method of manufacturing a semiconductor device in which a second semiconductor chip is bonded to a surface of a first semiconductor chip. The method includes: a back side grinding step for grinding the back side of a wafer including a device area where a plurality of first semiconductor chips are formed, the grinding applied to an area corresponding to the device area, so as to reduce the thickness of the wafer in the device area to a predetermined finished thickness; a chip bonding step for bonding the second semiconductor chip to a predetermined position of the surface of each of the first semiconductor chips formed on the face-side surface of the wafer; and a wafer dividing step for dividing the wafer along streets to separate the device area of the wafer into individual semiconductor devices in each of which the second semiconductor chip is bonded to the surface of the first semiconductor chip.

### BACKGROUND OF THE INVENTION

1. Field of the Invention

The present invention relates to a method of manufacturing a semiconductor device of a so-called chip-on-chip structure fabricated by bonding a second semiconductor chip onto a surface of a first semiconductor chip.

2. Description of the Related Art

A semiconductor device of the so-called chip-on-chip structure is fabricated by bonding a second semiconductor chip (secondary chip) smaller than a first semiconductor chip (primary chip) to a predetermined position on a surface of the first semiconductor chip, and interconnecting a bonding pad provided for the first semiconductor chip and a bonding pad provided for the second semiconductor chip by wire bonding. In addition, by use of a flip-chip bonding technology, the bonding pad formed on the surface of the first semiconductor chip (primary chip) and an electrode bump formed on the second semiconductor chip (secondary chip) are bonded to each other to fabricate a semiconductor device of the chip-on-chip structure.

The semiconductor devices of the chip-on-chip structure as above-mentioned are manufactured by assembling them one by one. Therefore, each time of assembling the semiconductor device, a step of feeding and disposing the semiconductor chips and a step of detecting the position of each of the semiconductor chips have to be carried out, which is a problem from the viewpoint of productivity. In order to solve the just-mentioned problem, a method of manufacturing a semiconductor device has been disclosed in Japanese Patent No. 3422479 and Japanese Patent Laid-open No. Hei 6-151701 in which, before a wafer provided with a plurality of first semiconductor chips is divided into the individual semiconductor devices, a second semiconductor chip is bonded to a surface of each of the first semiconductor chips, and thereafter the wafer provided with the first semiconductor chips is divided into the individual semiconductor devices, thereby manufacturing the semiconductor device in which the second semiconductor chip is bonded to the surface of the first semiconductor chip.

### SUMMARY OF THE INVENTION

In this case, since the second semiconductor chip which is comparatively small is bonded to the surface of each of the plurality of first semiconductor chips formed on the wafer, the operation of grinding the back side of the wafer to thin the wafer may lead to breakage of the wafer due to concentration of stress under the grinding pressure. Therefore, in the case of grinding the back side of the wafer provided with the plurality of first semiconductor chips after the second semiconductor chips are bonded respectively to the first semiconductor chips, the limit in thinning the wafer is about 300 μm, and it is difficult to achieve a reduction in wafer thickness to 100 μm or below. On the other hand, where the back side of the wafer provided with the first semiconductor chips is ground to obtain a wafer thickness of 100 μm or below before the second semiconductor chips are bonded respectively to the first semiconductor chips on the wafer, the rigidity of the wafer is so lowered that the wafer is difficult to handle in the subsequent steps.

Accordingly, it is an object of the present invention to provide a method of manufacturing a semiconductor device by which a first semiconductor chip constituting a primary chip can be formed in a small thickness and a semiconductor device having a second semiconductor chip bonded to a surface of the first semiconductor chip can be manufactured efficiently.

In accordance with an aspect of the present invention, there is provided a method of manufacturing a semiconductor device having a second semiconductor chip smaller than a first semiconductor chip and bonded to a surface of the first semiconductor chip, the method including: a protective member adhering step for adhering a protective member on a face-side surface of a wafer, the wafer including a device area where a plurality of regions are demarcated by a plurality of streets formed in a grid pattern on a face-side surface of the wafer and the first semiconductor chip is formed in each of the demarcated regions and a peripheral marginal area surrounding the device area; a back side grinding step for holding the face-side surface of the wafer, the protective member being adhered to the face-side surface of the wafer, and for grinding a back side of the wafer, the grinding applied to an area corresponding to the device area, so as to reduce the thickness of the wafer in the device area to a predetermined finished thickness and to leave intact that area of a back-side surface of the wafer which corresponds to the peripheral marginal area, thereby forming an annular reinforcement portion; a chip bonding step for peeling the protective member having been adhered to the face-side surface of the wafer having been subjected to the back side grinding step and bonding the second semiconductor chip to a predetermined position of the surface of each of the first semiconductor chips formed on the face-side surface of the wafer; and a wafer dividing step for dividing the wafer having been subjected to the chip bonding step along the streets to separate the wafer into individual semiconductor devices in each of which the second semiconductor chip is bonded to the surface of the first semiconductor chip.

Prior to carrying out the wafer dividing step, a resin molding step for molding a resin onto each of the second semiconductor devices bonded respectively to the surfaces of the first semiconductor chips and a flattening step for grinding an upper surface of the molded resin so as to flatten the surface of the resin are carried out.

According to the present invention, the back side grinding step is conducted, whereby that area of the back-side surface of the wafer provided with the first semiconductor chips which corresponds to the device area is ground so as to thin the wafer in the device area to a finished thickness, and that area of the back-side surface of the wafer which corresponds to the peripheral marginal area is left intact so as to form an annular reinforcement portion. This ensures that even when the thickness of the wafer in the device area where the first semiconductor chips are formed is reduced, the rigidity of the wafer is secured by the presence of the annular reinforcement portion, so that the wafer can be handled without problem in the subsequent steps. Therefore, the first semiconductor chip constituting a primary chip can be formed in a reduced thickness, and the second semiconductor chips can be bonded respectively to the surfaces of the first semiconductor chips in the condition that the first semiconductor chips are formed on the wafer. Accordingly, the semiconductor device in which the second semiconductor chip is bonded to the surface of the first semiconductor chip can be manufactured efficiently.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a wafer provided with a plurality of first semiconductor chips to be used in a method of manufacturing a semiconductor device according to the present invention;

FIGS. 2A and 2B are respectively a perspective view of a wafer provided with a plurality of second semiconductor chips to be used in the method of manufacturing the semiconductor device according to the invention and a perspective view of the semiconductor device;

FIGS. 3A and 3B illustrate a protective member adhering step in the method of manufacturing the semiconductor device according to the invention;

FIG. 4 is a perspective view of a grinder for carrying out a back side grinding step in the method of manufacturing the semiconductor device according to the invention;

FIG. 5 illustrates the back side grinding step in the method of manufacturing the semiconductor device according to the invention;

FIG. 6 is a sectional view of a wafer formed by carrying out the back side grinding step illustrated in FIG. 5;

FIGS. 7A and 7B illustrate a chip bonding step in the method of manufacturing the semiconductor device according to the invention; FIG. 8 is a perspective view of a wafer having undergone the chip bonding step shown in FIG. 7;

FIG. 9 is an enlarged view of a major part showing the condition where the wafer having undergone the chip bonding step shown in FIG. 8 is subjected to wire bonding;

FIG. 10 is an enlarged view of a major part of a wafer having undergone a resin molding step in the method of manufacturing the semiconductor device according to the invention;

FIGS. 11A to 11C illustrate a flattening step in the method of manufacturing the semiconductor device according to the invention;

FIGS. 12A and 12B illustrate a wafer supporting step in the method of manufacturing the semiconductor device according to the invention;

FIG. 13 is a perspective view of a cutting apparatus for carrying out a wafer dividing step in the method of manufacturing the semiconductor device according to the invention;

FIGS. 14A and 14B illustrate the wafer dividing step in the method of manufacturing the semiconductor device according to the invention;

FIG. 15 is a perspective view of a semiconductor wafer having undergone the wafer dividing step shown in FIGS. 14A and 14B; and

FIG. 16 is a perspective view of a semiconductor device manufactured by the method of manufacturing the semiconductor device according to the invention.

### DETAILED DESCRIPTION OF THE PREFERRED EMBODIMENT

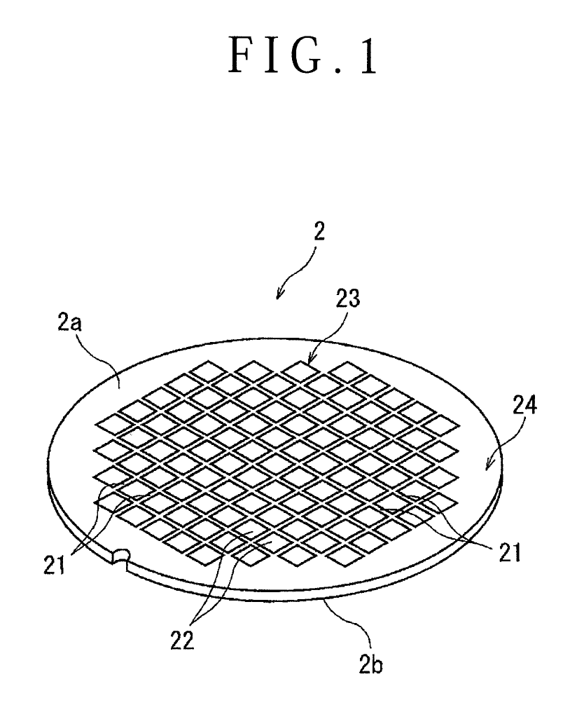

Now, a preferred embodiment of the method of manufacturing a semiconductor device according to the present invention will be described in detail below referring to the accompanying drawings. FIG. 1 shows a perspective view of a wafer provided with a plurality of first semiconductor chips to be used in the method of manufacturing the semiconductor device according to the invention. The wafer 2 shown in FIG. 1 is composed, for example, of a silicon wafer having a thickness of 700 μm, wherein a face-side surface is formed with a plurality of streets 21 in a grid pattern, and a first semiconductor chip 22 to be a primary chip such as IC, LSI, etc. is formed in each of a plurality of regions demarcated by the streets 21. The wafer 2 configured in this manner has a device area 23 where the first semiconductor chips 22 are formed, and a peripheral marginal area 24 surrounding the device area 23.

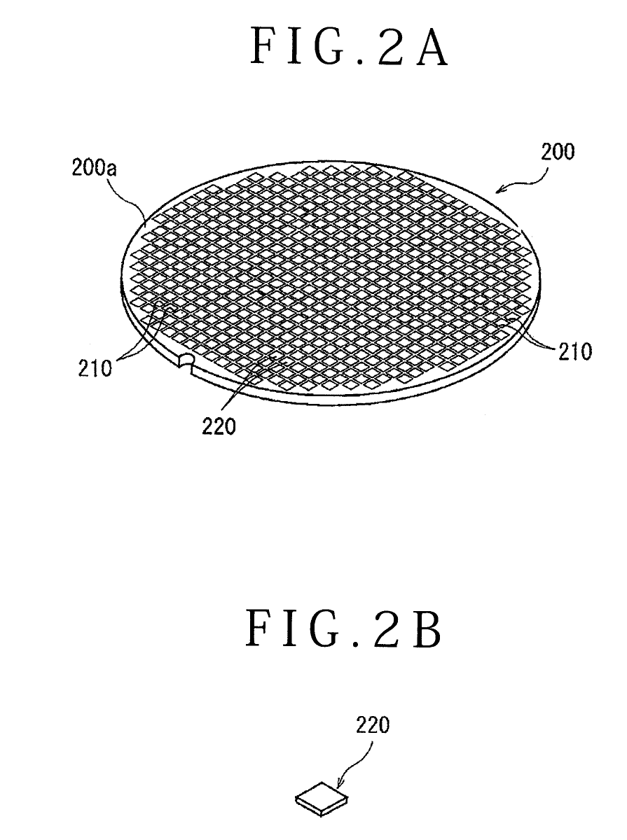

Besides, FIG. 2A shows a perspective view of a wafer provided with a plurality of second semiconductor chips to be used in the method of manufacturing the semiconductor device according to the present invention. The wafer 200 shown in FIG. 2A has a face-side surface 200a formed with a plurality of streets 210 in a grip pattern, and a second semiconductor chip 220 to be a secondary chip such as IC, LSI, etc. is formed in each of a plurality of regions demarcated by the streets 210. The wafer 200 thus configured has its back side ground to obtain a predetermined wafer thickness, and is then cut along the streets 210 by a dicing apparatus such as a cutting apparatus, to be divided into the individual second semiconductor chips 220 as shown in FIG. 2B. Incidentally, the second semiconductor chip 220 is smaller in size than the first semiconductor chip 22.

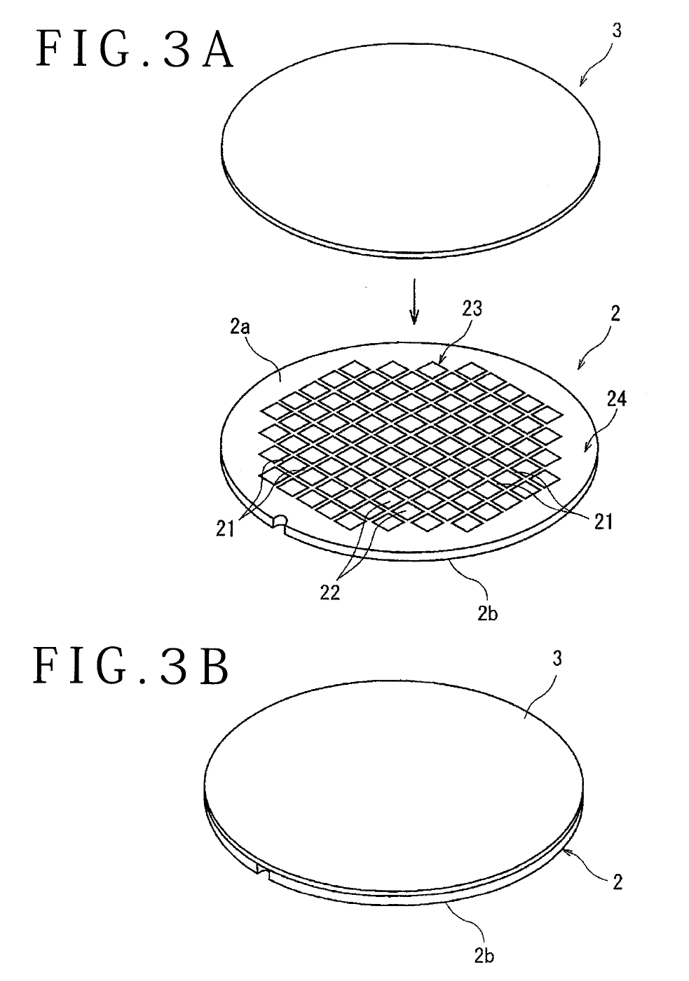

In carrying out the method of manufacturing the semiconductor device according to the present invention by using the wafer 2 provided with the plurality of the first semiconductor chip 22 and using also the second semiconductor chips 220, first, a protective member 3 for protecting the plurality of first semiconductor devices 22 is adhered to the face-side surface 2a of the wafer 2 provided with the first semiconductor chips 22, as shown in FIG. 3 (protective member adhering step).

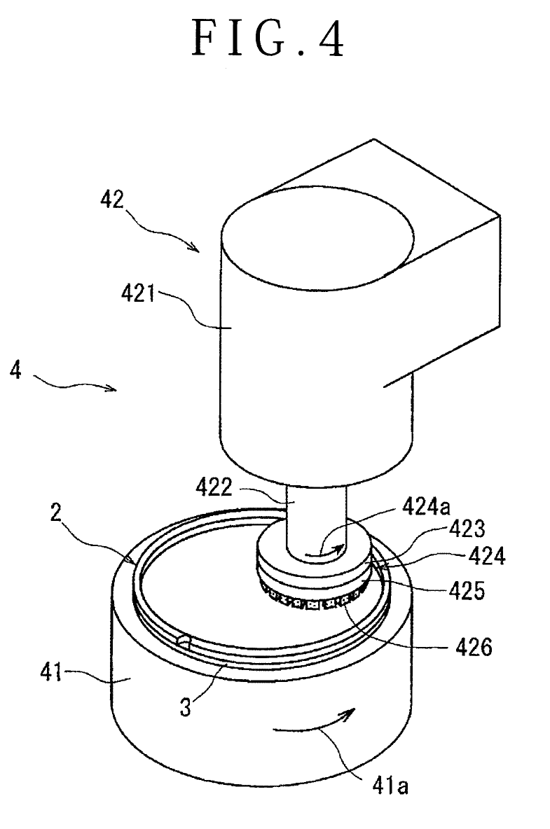

After the protective member adhering step is conducted, a back side grinding step is carried out in which that area of a back-side surface 2b of the wafer 2 provided with the first semiconductor chips 22 which corresponds to the device area 23 is ground to reduce the thickness of the wafer 2 in the device area 23 to a predetermined finished thickness, whereas that area of the back-side surface 2b of the wafer 2 which corresponds to the peripheral marginal area 24 is left intact, so as to form an annular reinforcement portion. This back side grinding step is carried out by a grinder shown in FIG. 4.

The grinder 4 shown in FIG. 4 includes a chuck table 41 for holding the wafer as a work, and grinding means 42 for grinding a work surface of the wafer held on the chuck table 41. The chuck table 41 holds the wafer on its upper surface by suction, and is rotated in the direction indicated by arrow 41a in FIG. 4. The grinding means 42 includes a spindle housing 421, a rotating spindle 422 rotatably supported on the spindle housing 421 and rotated by a rotational driving mechanism (not shown), a mounter 423 secured to the lower end of the rotating spindle 422, and a grinding wheel 424 attached to a lower surface of the mounter 423. The grinding wheel 424 is composed of a circular disk-shaped base 425, and grindstone pieces 426 mounted to a lower surface of the base 425 in an annular pattern, and the base 425 is secured to the lower surface of the mounter 423.

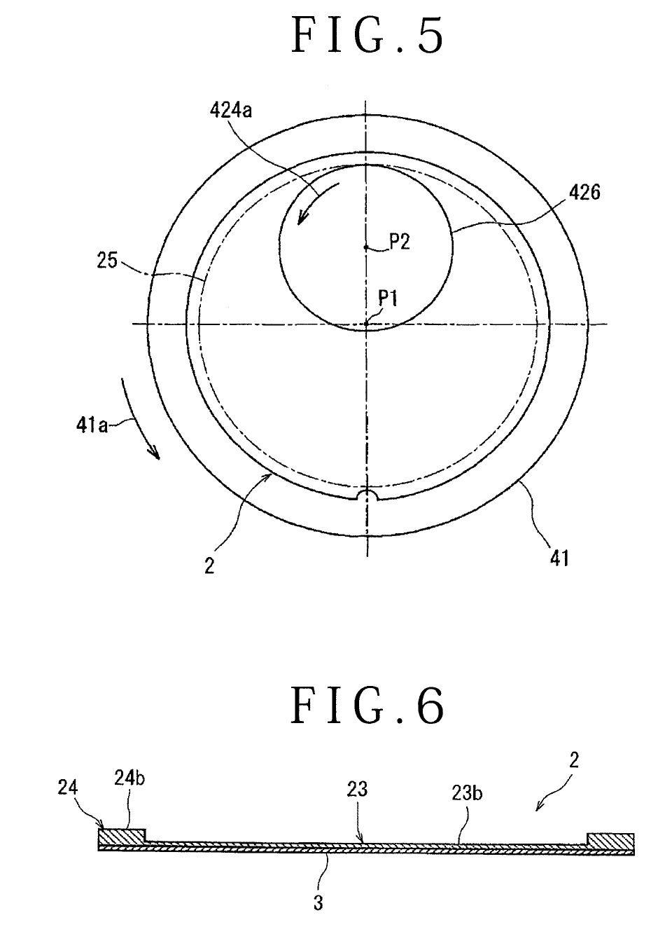

In carrying out the back side grinding step by use of the above-mentioned grinder 4, the semiconductor wafer 2 fed by wafer feeding-in means (not shown) is mounted on an upper surface (holding surface) of the chuck table 41, with the protective member 3 side in contact with the chuck table 41, and the semiconductor wafer 2 is suction held onto the chuck table 41. Here, the relationship between the semiconductor wafer 2 held on the chuck table 41 and the annularly arranged grindstone pieces 426 constituting the grinding wheel 424 will be described, referring to FIG. 5. The center of rotation P1 of the chuck table 41 and the center of rotation P2 of the annularly arranged grindstone pieces 426 are in an eccentric relation, and the outside diameter of the annularly arranged grindstone pieces 426 is set to be smaller than the diameter of a boundary line 25 between the device area 23 and the peripheral marginal area 24 of the wafer 2 and to be greater than the radius of the boundary line 25; in addition, the annularly arranged grindstone pieces 426 are so set as to pass through the center of rotation P1 of the chuck table 41 (namely, the center of the semiconductor wafer 2).

Next, while rotating the chuck table 41 at 300 rpm in the direction indicated by arrow 41a as shown in FIGS. 4 and 5, the grinding wheel 424 is rotated at 6000 rpm in the direction indicated by arrow 424a, and the grinding wheel 424 is moved downwards to bring the grindstone pieces 426 into contact with the back-side surface of the semiconductor wafer 2. Then, the grinding wheel 424 is fed for grinding by a predetermined amount downwards at a predetermined grinding feed rate. As a result, on the back side of the semiconductor wafer 2, as shown in FIG. 6, the area corresponding to the device area 23 is ground away to form a circular recessed portion 23b in a predetermined thickness (for example, 30 μm), whereas the area corresponding to the peripheral marginal area 24 is left intact, specifically, left in a thickness of 700 μm in the embodiment shown, to form an annular reinforcement portion 24b (back side grinding step). Thus, the semiconductor wafer 2 in the device area 23 where the plurality of first semiconductor chips 22 are formed is thinned to an extremely small thickness of 30 μm, but the rigidity of the wafer 2 is secured by the presence of the annular reinforcement portion 24b, so that the wafer 2 can be handled without problem in the subsequent steps.

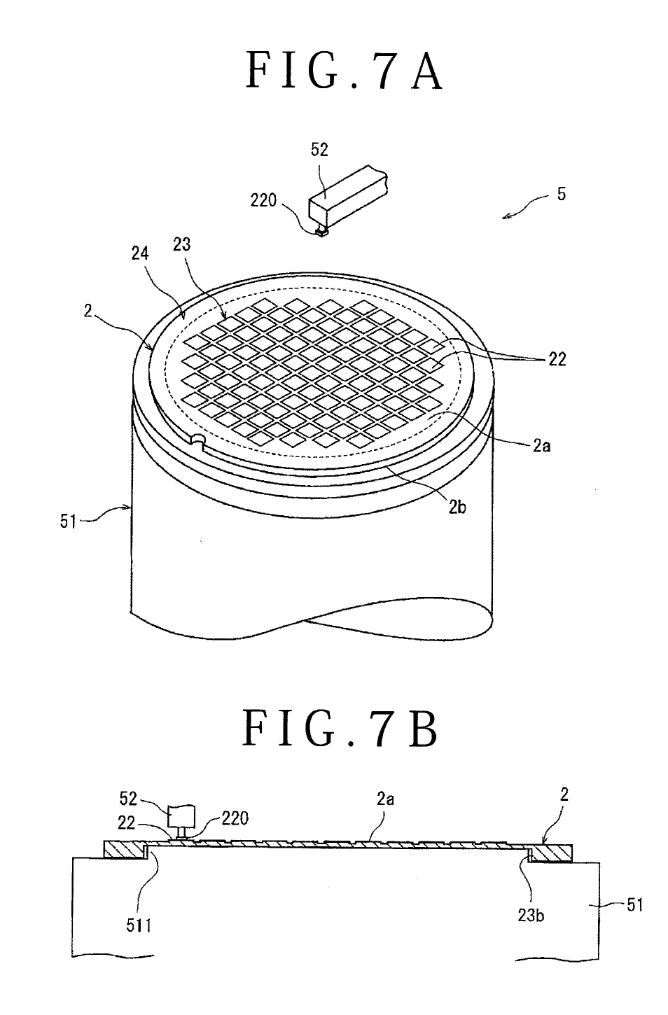

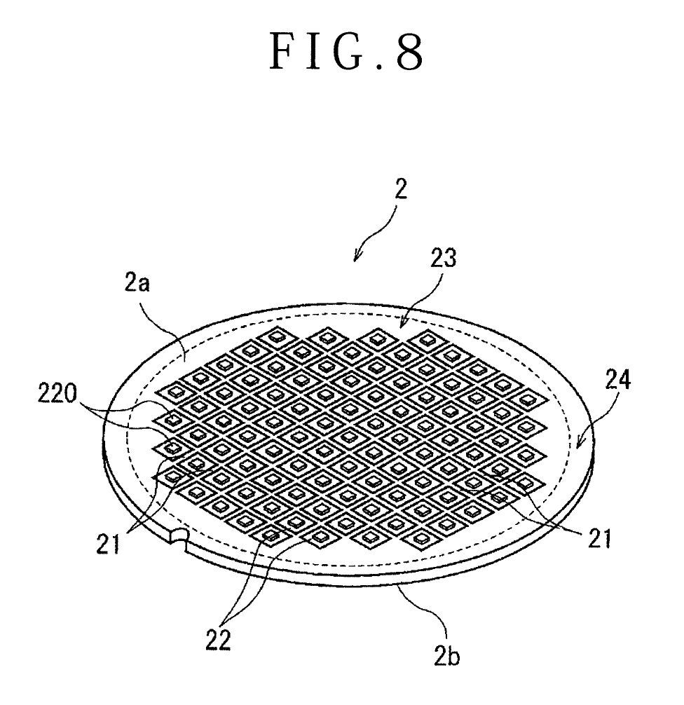

After the back side grinding as above-mentioned is conducted, a chip bonding step is carried out in which the above-mentioned second semiconductor chips 220 are bonded respectively to predetermined positions on the surfaces of the plurality of first devices 22 formed on the surface of the wafer 2 having undergone the back side grinding step. This chip bonding step will be described referring to FIGS. 7A, 7B and 8. As shown in FIGS. 7A and 7B, the wafer 2 having undergone the back side grinding step as above-mentioned is mounted on a holding table 51 of a bonding apparatus 5, with its back-side surface 2b in contact with the holding table 51. Incidentally, as shown in FIG. 7B, an upper surface of the holding table 51 is provided with a circular stepped portion 511 to be fitted into the circular recessed portion 23b formed on the back side of the wafer 2. Therefore, the circular recessed portion 23b formed on the back side of the wafer 2 is fitted onto the circular stepped portion 511 of the holding table 51, whereby the wafer 2 is held onto the holding table 51. Incidentally, the protective member 3 having been adhered to the face-side surface 2a of the wafer 2 is peeled off when or after the wafer 2 is held onto the holding table 51.

After the wafer 2 is held onto the holding table 51 in this manner, the second semiconductor chip 220 shown in FIG. 2B is suction held by a sucker hand 52, and is fed to the upper side of a predetermined one of the first semiconductor chips 22 formed on the wafer 2 held on the holding table 51. Then, alignment between a predetermined position of the first semiconductor chip 22 and the second semiconductor chip 220 is conducted, and the sucker hand 52 is lowered as shown in FIG. 7B, whereby the second semiconductor chip 220 is bonded to the predetermined position of the first semiconductor chip 22. This chip bonding step is carried out for all the first semiconductor chips 22 formed on the wafer 2, as shown in FIG. 8.

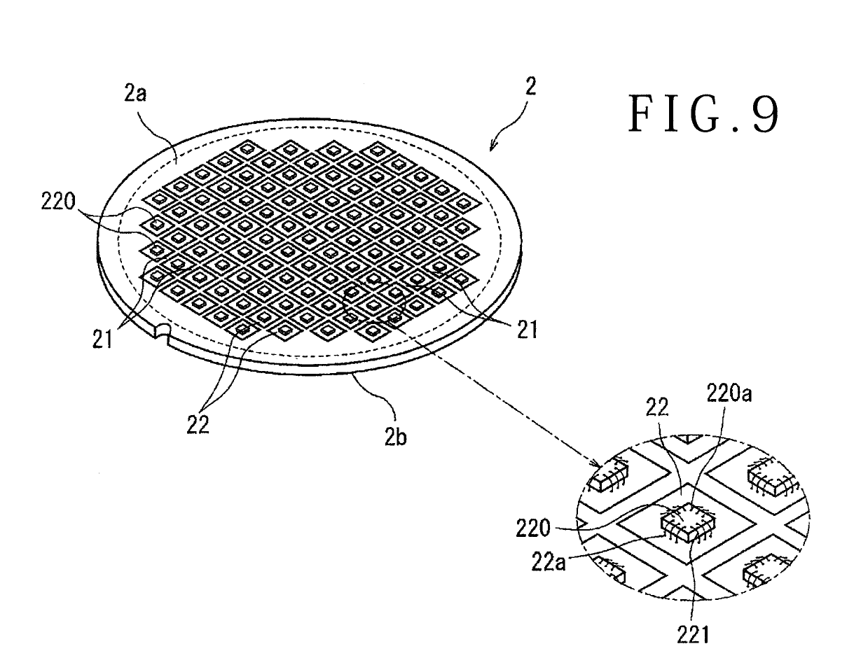

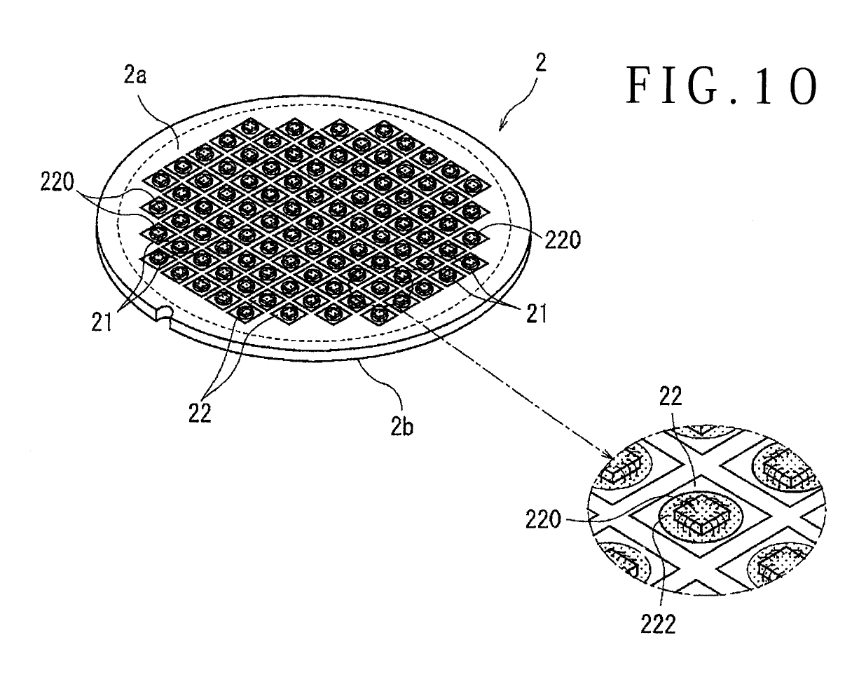

Incidentally, the bonding of the second semiconductor chip 220 to the first semiconductor chip 22 in the chip bonding step can be performed by use of an appropriate adhesive or adhesive film. Then, as shown in FIG. 9, a bonding pad 22a provided on the first semiconductor chip 22 and a bonding pad 220a provided on the second semiconductor chip 220 are interconnected through wires 221 by a wire bonding method. Besides, the bonding of the second semiconductor chip 220 to the first semiconductor chip 22 can be carried out by use of a flip-chip bonding technique, in which the bonding pad formed on the surface of the first semiconductor chip 22 and an electrode bump formed on the second semiconductor chip 220 are made to face each other, and bonding is conducted. After the chip bonding step is conducted, a resin molding step is carried out in which the second semiconductor chip 220 bonded to the first semiconductor chip 22 is potted with a resin molded thereon. Specifically, as shown in FIG. 10, a resin 222 is dropped onto the second semiconductor chip 220 bonded to the surface of the first semiconductor chip 22, for molding the resin 222 onto the second semiconductor chip 220.

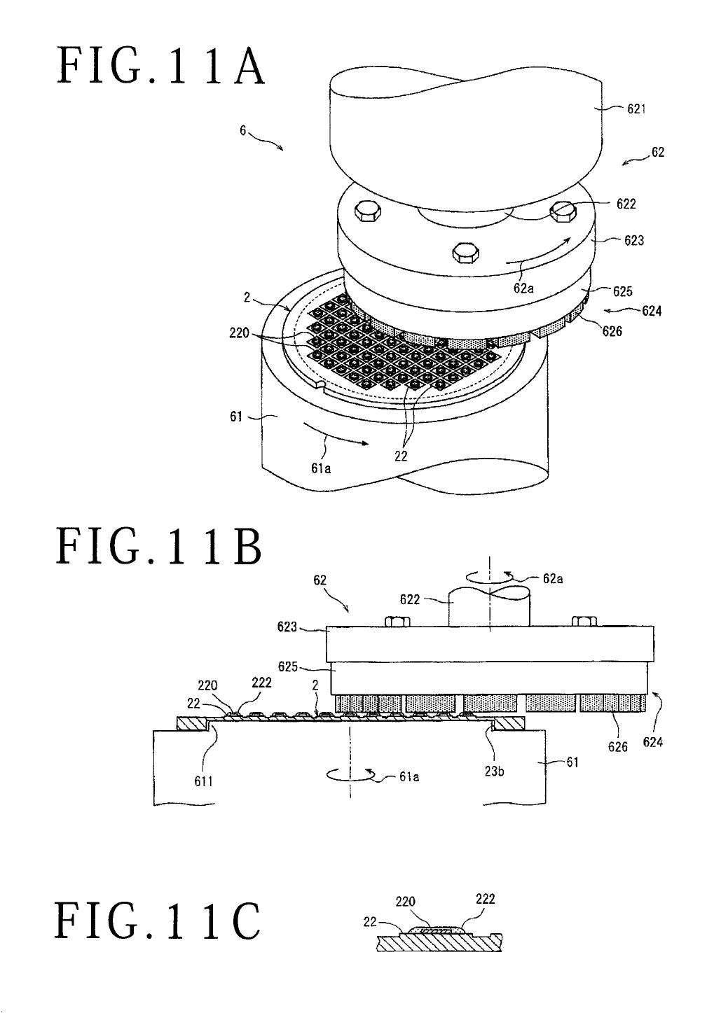

Subsequently, a flattening step is carried out in which an upper surface of the resin 222 molded onto the second semiconductor chip 220 bonded to the surface of the first semiconductor chip 22 is ground to be flat. The flattening step is performed by use of a grinder shown in FIGS. 11A and 11B. The grinder 6 shown in FIGS. 11A and 11B, like the grinder 4 shown in FIG. 4 above, includes a chuck table 61 for holding a wafer as a work, and grinding means 62 for grinding a work surface of the wafer held on the chuck table 61. The chuck table 61 holds the wafer on its upper surface by suction, and is rotated in the direction of arrow 61a in FIG. 11A. The grinding means 62 includes a spindle housing 621, a rotating spindle 622 rotatably supported on the spindle housing 621 and rotated by a rotational driving mechanism (not shown), a mounter 623 secured to the lower end of the rotating spindle 622, and a grinding wheel 624 attached to a lower surface of the mounter 623. The grinding wheel 624 includes a circular disk-shaped base 625, and grindstone pieces 626 mounted to a lower surface of the base 625 in an annular pattern, and the base 625 is attached to the lower surface of the mounter 623.

Incidentally, in the grinder 6 shown in FIGS. 11A and 11B, the grinding wheel 624 used is greater in diameter than the grinding wheel 624 of the grinder 4 shown in FIG. 4 above. In addition, an upper surface of the chuck table 61 is provided with a circular stepped portion 611 to be fitted into the above-mentioned circular recessed portion 23b formed on the back side of the wafer 2, as shown in FIG. 11B. Therefore, the circular recessed portion 23b formed on the back side of the wafer 2 is fitted onto the circular stepped portion 611 of the chuck table 61, and suction means (not shown) is operated, whereby the wafer 2 having undergone the resin molding step is suction held onto the chuck table 61. After the wafer 2 having been subjected to the resin molding step is held onto the chuck table 61 in this manner, the chuck table 61 is rotated, for example, at 300 rpm in the direction indicated by arrow 61a. While keeping this condition, the grinding wheel 624 of the grinding means 62 is rotated, for example, at 6000 rpm in the direction indicated by arrow 62a, and is brought into contact with the upper surface of the resin 222 molded onto each second semiconductor chip 220 bonded to the surface of the first semiconductor chip 22. As a result, a top portion of the resin 222 molded onto each second semiconductor chip 220 is ground to be flat, as shown in FIG. 11C.

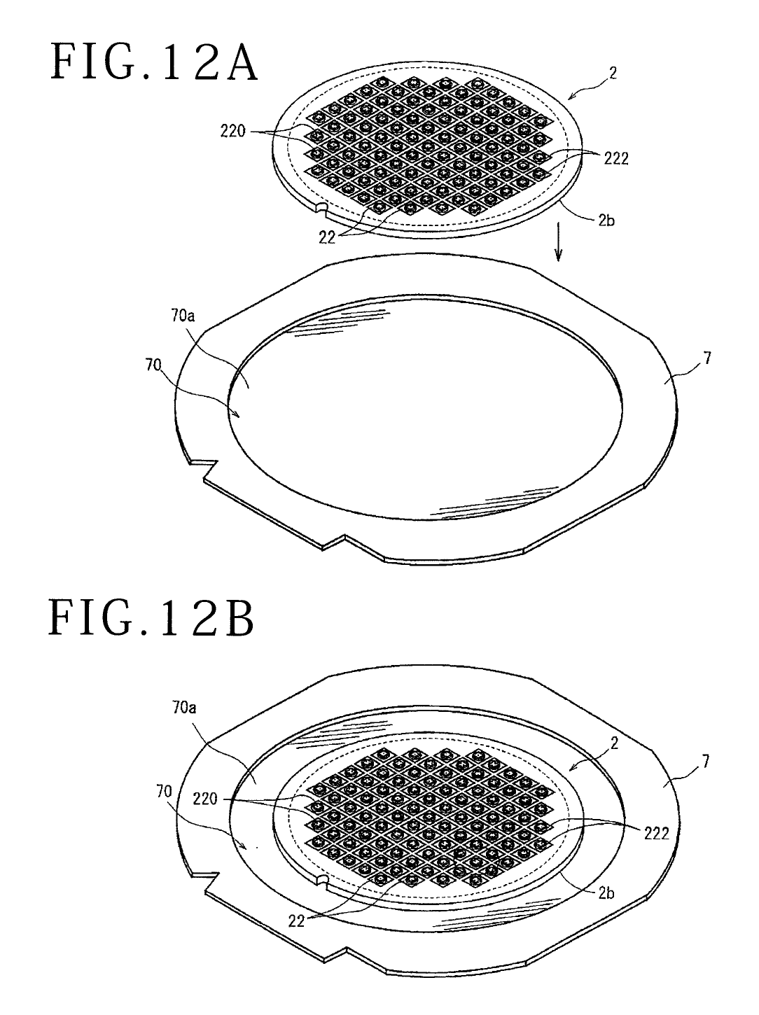

Next, a wafer supporting step is carried out in which the back side of the wafer 2 having been subjected to the flattening step is adhered to a dicing tape mounted to an annular frame. As shown in FIG. 12A, the dicing tape 70 composed of a sheet of a synthetic resin such as polyolefin having its peripheral portion mounted to the annular frame 7 so as to cover an inside aperture portion of the frame 7 is prepared, and the back-side surface 2b of the wafer 2 is adhered to a face-side surface 70a of the dicing tape 70.

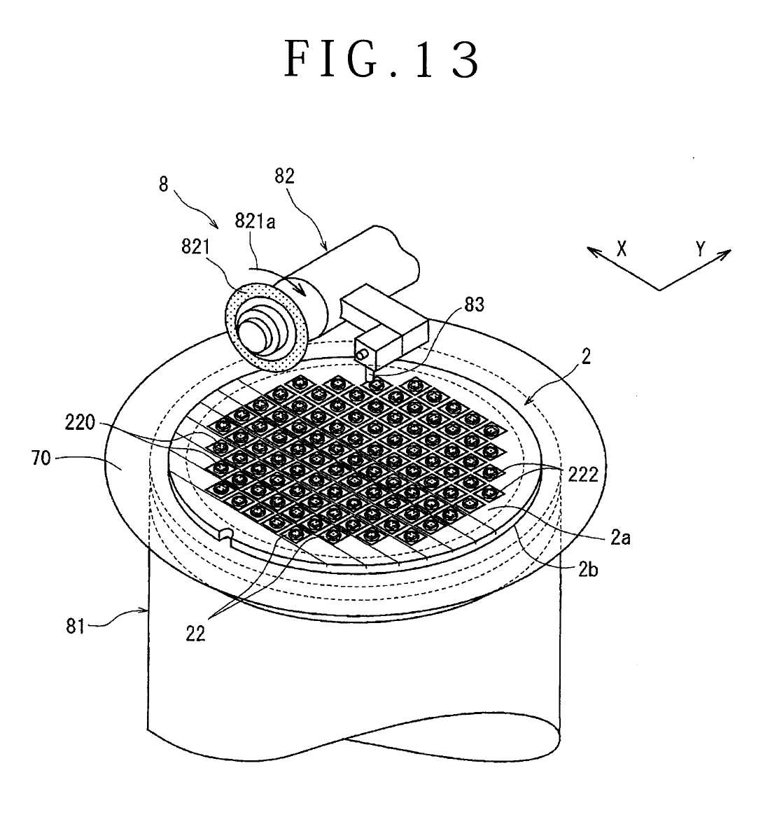

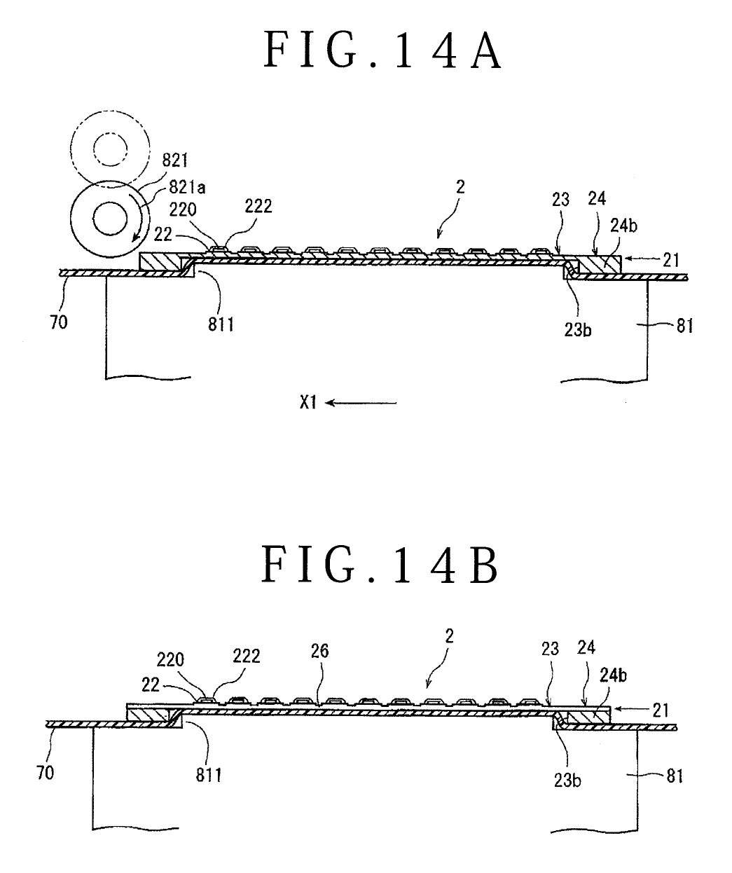

After the wafer supporting step as just-mentioned is conducted, a wafer dividing step is carried out in which the wafer 2 is divided along the streets 21 into individual semiconductor devices in each of which the second semiconductor chip 220 is bonded to the surface of the first semiconductor chip 22. The wafer dividing step is conducted by use of a cutting apparatus shown in FIGS. 13 to 14B. The cutting apparatus 8 shown in FIGS. 13 to 14B includes a chuck table 81 for holding a work, a cutting means 82 having a cutting blade 821, and image pickup means 83. The chuck table 81 is configured to hold the work by suction. The chuck table 81 is configured to be moved in a cutting feed direction indicated by arrow X in FIG. 13 by cutting feeding means (not shown), and to be moved in an indexing feed direction indicated by arrow Y by an indexing feeding means (not shown).

Incidentally, an upper surface of the chuck table 81 is provided with a circular stepped portion 811 to be fitted into the above-mentioned circular recessed portion 23b formed on the back side of the wafer 2, as shown in FIGS. 14A and 14B. In carrying out the wafer dividing step by the cutting apparatus 8, the assembly of the wafer 2 and the dicing tape 70 to which the back-side surface 2b of the wafer 2 is adhered is mounted on the chuck table 81, with the dicing tape 70 side in contact with the chuck table 81. Then, a suction means (not shown) is operated, whereby the wafer 2 is held onto the chuck table 81. Incidentally, while the annular frame 7 to which the dicing tape 70 is mounted is omitted in FIG. 13, the annular frame 7 is held by appropriate frame holding means arranged at the chuck table 81.

The chuck table 81 with the wafer 2 thus suction held thereon is positioned into a position directly under the image pickup means 83 by the cutting feeding means (not shown). After the chuck table 81 is positioned into the position directly under the image pickup means 83, an alignment work is carried out in which a cutting region (a region to be cut) of the wafer 2 is detected by the image pickup means 83 and control means (not shown). Specifically, the image pickup means 83 and the control means (not shown) perform image processing such as pattern matching for aligning (position matching) between the street 21 formed in a predetermined direction on the wafer 2 and the cutting blade 821, whereby alignment of the cutting region is performed (alignment step). In addition, similar alignment of a cutting region is performed also for the street 21 formed on the wafer 2 and extending in the direction orthogonal to the predetermined direction.

After the alignment of the cutting region for the wafer 2 held on the chuck table 81 is performed in this manner, the chuck table 81 with the wafer 2 held thereon is moved to a cutting starting position for the cutting region. In this instance, as shown in FIG. 14A, the wafer 2 is so positioned that one end (the left end in FIG. 14A) of the predetermined street 21 is located at a position deviated by a predetermined amount to the right side from the position directly under the cutting blade 821. Then, the cutting blade 821 is rotated at a predetermined rotating speed in the direction indicated by arrow 821a in FIG. 14A, and, while keeping this condition, the cutting blade 821 is subjected to infeed from a stand-by position indicated by two-dotted chain line by a predetermined amount downwards, as indicated by solid line in FIG. 14A, by an infeed means (not shown). The infeed position in this case is so set that a peripheral edge of the cutting blade 821 reaches that back-side surface 2b (the lower surface in FIG. 14A) of the wafer 2 which corresponds to the device area 23, namely, the surface of the dicing tape 70.

After the infeed of the cutting blade 821 is thus performed, the cutting blade 821 is rotated at the predetermined rotating speed in the direction of arrow 821a in FIG. 14A, and, while keeping this condition, the chuck table 81 is moved at a predetermined cutting feed speed in the direction indicated by arrow X1 in FIG. 14A. Thereafter, when the right end of the wafer 2 held on the chuck table 81 has just passed through the position directly under the cutting blade 821, the movement of the chuck table 81 is stopped. Consequently, as shown in FIG. 14B, the wafer 2 is provided with a dividing groove 26 extending from the face-side surface 2a of the wafer 2 to reach that back-side surface (the lower surface in FIG. 14B) which corresponds to the device area 23 of the wafer 2.

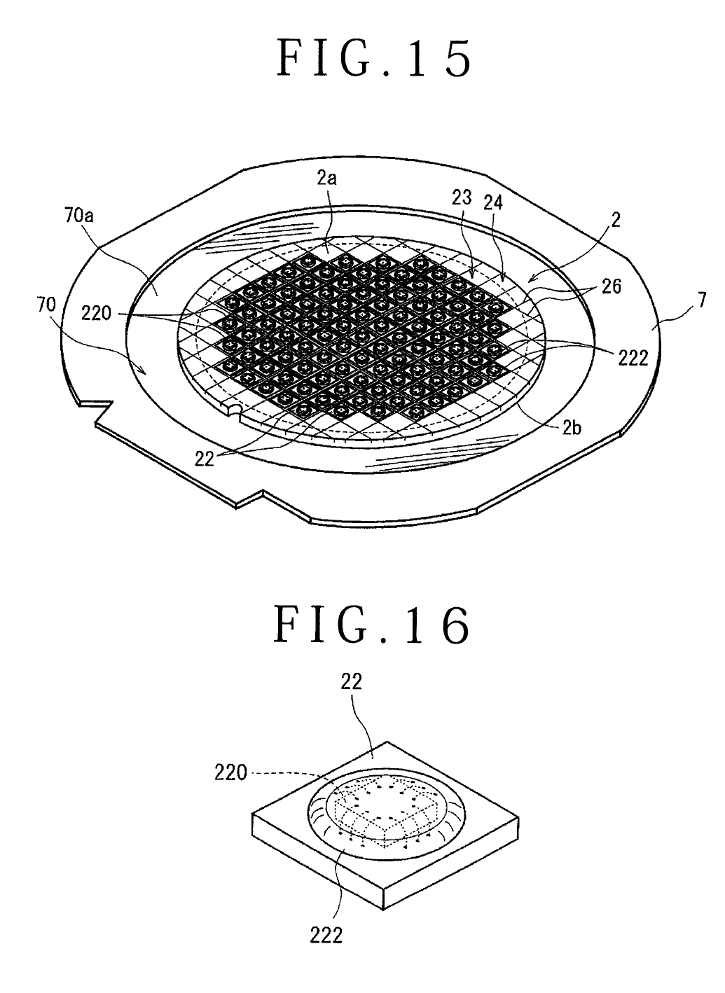

After the dividing grooves 26 are formed along all the streets 21 formed on the wafer 2 to extend in the predetermined direction in this manner, the chuck table 81 is turned by 90 degrees, and the diving grooves 26 are similarly formed along the streets 21 extending in the direction orthogonal to the predetermined direction. Consequently, as shown in FIG. 15, the device area 23 is divided along the streets 21 so as to be separated into individual semiconductor devices in each of which the second semiconductor chip 220 is bonded to the surface of the first semiconductor chip 22. Incidentally, the peripheral marginal area 24 surrounding the device area 23 retains its original annular form, since the dividing groove 26 are not reaching the back-side surface of the annular reinforcement portion 24b in this area.

After the device area 23 of the wafer 2 is divided into the individual devices by carrying out the wafer dividing step in the above-mentioned manner, each first semiconductor chip 22 (with the second semiconductor chip 220 bonded to the surface thereof) is peeled from the protective tape 70 and picked up, whereby the semiconductor device in which the second semiconductor chip 220 is bonded to the surface of the first semiconductor chip 22 is obtained, as shown in FIG. 16.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of manufacturing a semiconductor device having a second semiconductor chip smaller than a first semiconductor chip and bonded to a surface of the first semiconductor chip, the method comprising:
a back side grinding step for grinding a back side of a wafer, the wafer including a device area where a plurality of regions are demarcated by a plurality of streets formed in a grid pattern on a face-side surface of the wafer and the first semiconductor chip is formed in each of the demarcated regions and a peripheral marginal area surrounding the device area, the grinding applied to an area corresponding to the device area, so as to reduce the thickness of the wafer in the device area to a predetermined finished thickness and to leave intact that area of a back-side surface of the wafer which corresponds to the peripheral marginal area, thereby forming an annular reinforcement portion;
a chip bonding step for bonding the second semiconductor chip to a predetermined position of a surface of each of the plurality of first semiconductor chips formed on the face-side surface of the wafer having been subjected to the back side grinding step; and
a wafer dividing step for dividing the wafer having been subjected to the chip bonding step along the streets to separate the wafer into individual semiconductor devices in each of which the second semiconductor chip is bonded to the surface of the first semiconductor chip.

2. The method according to claim 1, further comprising:
a resin molding step for molding a rein onto each of the second semiconductor chips bonded respectively to the surfaces of the first semiconductor chips, prior to the wafer dividing step; and
a flattening step for grinding an upper surface of the resin used for the resin molding so as to flatten the surface of the resin.
